(19) United States
(12) Patent Application Publication
(10) Pub. No.: US 2008/0239645 A1
(43) Pub. Date: Oct. 2, 2008

(54) Flat panel display having detachable supporting base

(75) Inventor: Qiang Li, Shenzhen (CN)

Correspondence Address: WEI TE CHUNG;FOXCONN INTERNATIONAL, INC., 1650 MEMOREX DRIVE, SANTA CLARA, CA, 95050, US

(73) Assignees: INNOCOM TECHNOLOGY (SHENZHEN) CO., LTD.; INNOLUX DISPLAY CORP.

(21) Appl. No.: 12/080,045

(22) Filed: Mar. 31, 2008

(30) Foreign Application Priority Data
Mar. 30, 2007 (CN) 200710073762.4

(51) Int. Cl. H05K 5/00

(52) U.S. Cl. 361/681

(57) ABSTRACT

An exemplary flat panel display includes a chassis, a locking apparatus fixed to the chassis, and a supporting base. The locking apparatus includes a mobile member and a releasing button. The mobile member includes at least one sliding surface and at least one first fixing protrusion. The releasing includes a button base corresponding to the at least one sliding surface, and at least one sliding rib provided at the button base. The at least one sliding rib is configured for sliding along the at least one sliding surface. The supporting base includes at least one second fixing protrusion. The at least one first fixing protrusion and the at least one second fixing protrusion are configured to fix to each other such that the supporting base is fixed to the locking apparatus.

### FIELD OF THE INVENTION

The present invention relates to a flat panel display (FPD) having a detachable supporting base that can be conveniently detached from a display body of the flat panel display.

### GENERAL BACKGROUND

Flat panel displays are commonly used as display devices for compact electronic apparatuses. Referring to FIG. 5, a typical flat panel display 5 includes a front frame 50, a display module 51, a chassis 52, a locking apparatus 53, a back cover 54, and a supporting base 55, arranged in that order from left to right as shown. When the flat panel display 5 is assembled, the front frame 50 and the back cover 54 cooperative accommodate the display module 51, with the chassis 52 attached to a back side (not labeled) of the display module 51, the locking apparatus 53 fixed to the chassis 52, and the supporting base 55 fixed to the locking apparatus 53.

Referring also to FIG. 6, the locking apparatus 53 includes a mobile member 530, a releasing button 531, and a button cap 532. The mobile member 530 includes two inclined sliding surfaces 533. The releasing button 531 has a declined bottom surface (not labeled) configured for coupling to the sliding surfaces 533 such that the bottom surface of the releasing button 531 can slide along the sliding surfaces 533. The button cap 532 is detachable from the releasing button 531. In an operation of detaching the supporting base 55 from the locking apparatus 53, the button cap 532 is pressed inward. The bottom surface of the releasing button 531 slides along the sliding surfaces 533, the mobile member 530 is thereby driven to move down, and the support base 55 is thereby released from the mobile member 530.

In the flat panel display 5, the bottom surface of the releasing button 531 is configured to frictionally slide along the sliding surfaces 533 of the mobile member 530 and thereby drive the mobile member 530 to move down. This generally requires a user to exert a great deal of force on the button cap 532 in order to start and maintain the surface-to-surface sliding movement. Therefore it can be inconvenient for the user to detach the support base 55 from the flat panel display 5. Furthermore, the button cap 532 is a separate piece from the releasing button 531, which adds to the steps required to assemble the flat panel display 5. Therefore the efficiency of mass production of the flat panel display 5 is limited.

What is needed, therefore, is a flat panel display that can overcome the above-described deficiencies.

### SUMMARY

In an exemplary embodiment, a flat panel display includes a chassis, a locking apparatus fixed to the chassis, and a supporting base. The locking apparatus includes a mobile member and a releasing button. The mobile member includes at least one sliding surface and at least one first fixing protrusion. The releasing includes a button base corresponding to the at least one sliding surface, and at least one sliding rib provided at the button base. The at least one sliding rib is configured for sliding along the at least one sliding surface. The supporting base includes at least one second fixing protrusion. The at least one first fixing protrusion and the at least one second fixing protrusion are configured to fix to each other such that the supporting base is fixed to the locking apparatus.

Other novel features, advantages and aspects will become more apparent from the following detailed description when taken in conjunction with the accompanying drawings.

### BRIEF DESCRIPTION OF THE DRAWINGS

The components in the drawings are not necessarily drawn to scale, the emphasis instead being placed upon clearly illustrating the principles of at least one embodiment of the present invention. In the drawings, like reference numerals designate corresponding parts throughout various views, and all the views are schematic.

FIG. 1 is an isometric view of a flat panel display according to an exemplary embodiment of the present invention.

FIG. 2 is an exploded view of the flat panel display of FIG. 1, the flat panel display including a locking apparatus and a back cover that includes a location member.

FIG. 3 is an enlarged, exploded, isometric view of the locking apparatus and the location member of FIG. 2, the locking apparatus including a releasing button.

FIG. 4 is an enlarged, isometric, inverted view of the releasing button of FIG. 3.

FIG. 5 is an exploded, isometric view of a conventional flat panel display, the flat panel display including a supporting base and a locking apparatus, the supporting base being configured to be fixed to the locking apparatus.

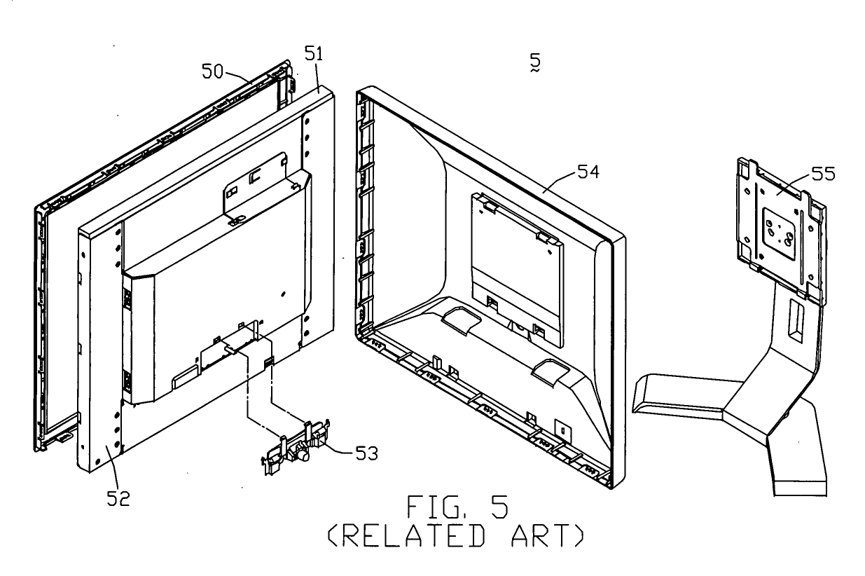

FIG. 6 is an enlarged, exploded view of the locking apparatus of FIG. 5.

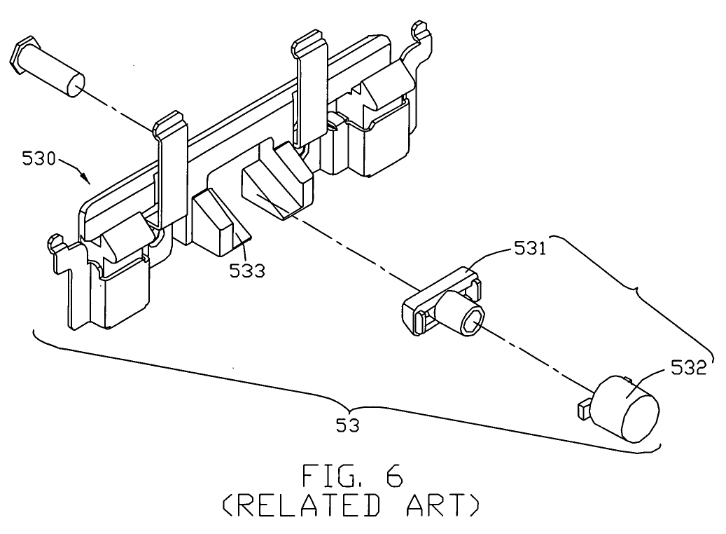

### DETAILED DESCRIPTION OF PREFERRED EMBODIMENTS

Reference will now be made to the drawings to describe preferred and exemplary embodiments in detail.

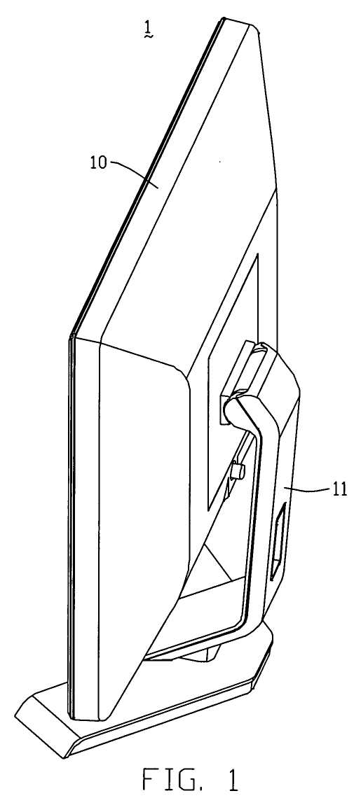

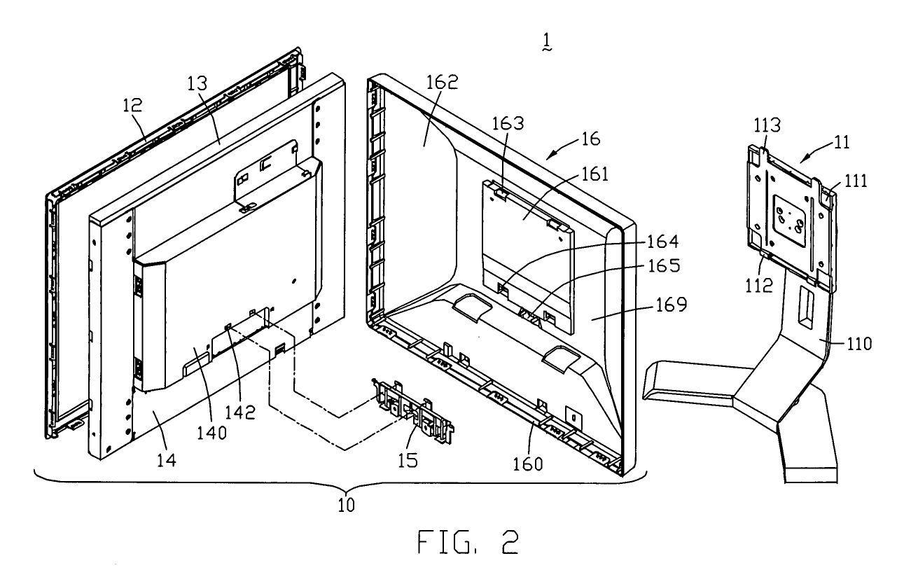

Referring to FIG. 1, a flat panel display 1 according to an exemplary embodiment of the present invention is shown. The flat panel display 1 includes a display body 10, and a supporting base 11 for supporting the display body 10. Referring also to FIG. 2, the display body 10 includes a front frame 12, a display module 13, a chassis 14, a locking apparatus 15, and a back cover 16, arranged in that order from left to right as shown.

The front frame 12 has a generally rectangular shape, and has a size which is slightly greater than a size of the display module 13. The front frame 12 includes a four-sided bezel portion (not labeled), thus defining a window (not labeled) for allowing viewing of the display module 13. The front frame 12 is preferably made from plastic, polymer, or another suitable material.

The chassis 14 is assembled to a back side of the display module 13, and includes an offset back wall 140. The back wall 140 is essentially box-shaped, and defines a rectangular aperture (not labeled) at a bottom portion thereof, and two fixing notches 142 above the aperture. The back wall 140 further includes an elastic member (not shown) arranged at a bottom portion of the aperture. The chassis 14 is preferably made from iron, steel, aluminum, magnesium, a suitable alloy of any of these metals, or another suitable alloy, such that the chassis 14 can shield electromagnetic interference (EMI) radiated by electrical components (not shown) of the display module 13 in a working state.

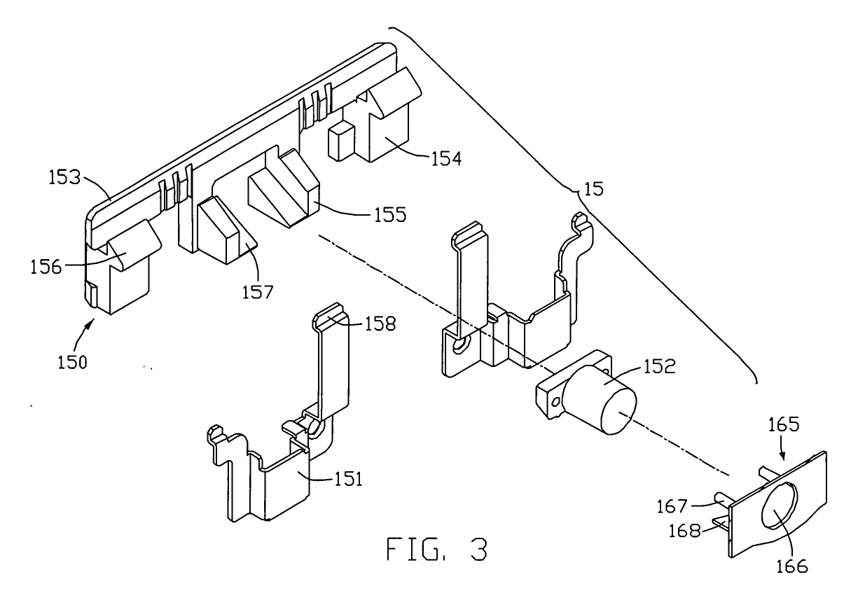

The back cover 16 includes a sub-frame 160, a rear wall 169, a sub-cover 161, and four side walls 162. The sub-frame 160 is generally rectangular, and has a size substantially the same as the size of the front frame 12. The sub-cover 161 is provided at a middle of the rear wall 169, and is in the form of a rectangular, shallow recessed portion as viewed from a rear of the back cover 16. That is, the sub-cover 161 protrudes inwardly from the rear wall 169 toward the sub-frame 160. The recess of the sub-cover 161 is configured for receiving a corresponding part of the supporting base 11 therein (see below). The sub-cover 161 defines a pair of top hatches 163 in a top portion thereof, and a pair of bottom hatches 164 in a bottom portion thereof. The side walls 162 cooperatively connect the sub-frame 160 with the rear wall 169. Thus the sub-frame 160, the side walls 162, the rear wall 169, and the sub-cover 161 cooperatively define a housing (not labeled), for accommodating the display module 13 assembled with the chassis 14, the locking apparatus 15, and other components (not shown) of the flat panel display 1. The rear wall 169 further includes a location member 165 positioned below the sub-cover 161. Referring also to FIG. 3, the location member 165 includes a location hole 166 defined therein, two location bolts 167 perpendicularly extending toward the aperture of the chassis 14, and a restricting board 168 arranged below the location hole 166.

The locking apparatus 15 includes a mobile member 150, two fixing brackets 151, and a releasing button 152. The mobile member 150 includes an essentially beam-shaped main body 153, two first blocks 154, and two second blocks 155. The first blocks 154 are respectively connected with bottom sides of two opposite end portions of the main body 153. Each first block 154 includes a first fixing protrusion 156 far from the main body 153. Thus two gaps (not labeled) are defined between the first fixing protrusions 156 and the main body 153, respectively. The gaps are aligned with each other. The second blocks 155 are connected with a bottom side of a central portion of the main body 155, and are between the first blocks 154. An opening (not labeled) is defined between the second blocks 155. Each second block 155 includes a sliding surface 157 declined in a direction away from the main body 153. In the illustrated embodiment, the first fixing protrusions 156 and the sliding surfaces 157 are at the same side of the main body 153. The fixing brackets 151 respectively correspond to the first blocks 154, and each fixing bracket 151 includes a fixing tip 158 at a top portion thereof. The fixing brackets 151 are fixed to the chassis 14, and can hold the mobile member 150 while allowing movement of the mobile member 150. In particular, the mobile member 150 is able to move up and down along the fixing brackets 151.

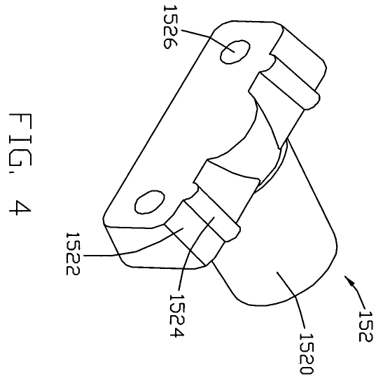

Referring also to FIG. 4, the releasing button 152 includes a button cap 1520, and a button base 1522 integrally (inseparably) formed with the button cap 1520. The button base 1522 includes two parallel sliding ribs 1524 provided on a bottom portion thereof, and two through holes 1526 defined therein. The button cap 1520 is located between the through holes 1526, and is typically made from a mixture of polyoxymethylene (POM) and glass fiber. A vertical thickness of the button base 1522 decreases with increasing distance away from the button cap 1520. An inclination of a bottom of the button base 1522 is substantially the same as that of the sliding surfaces 157. When the locking apparatus 15 is assembled, only a small ridge area of each sliding rib 1524 contacts the corresponding sliding surface 157. Therefore the sliding ribs 1524 can be conveniently driven to slide along the sliding surfaces 157 with only a relatively small amount of force being applied to the releasing button 152.

The supporting base 11 includes a supporting stand 110, and a releasing plate 111 connected with the supporting stand 110. The releasing plate 111 includes two second fixing protrusions 112, and two flat coupling ends 113. The second fixing protrusions 112 respectively correspond to the first fixing protrusions 156 of the mobile member 150. The coupling ends 113 of the releasing plate 111 respectively correspond to the top hatches 163 of the sub-cover 161 of the back cover 16.

The flat panel display 1 can be assembled as follows. First, the chassis 14 is fixed to the back side of the display module 13. Second, the locking apparatus 15 is fixed to the chassis 14. The locking apparatus 15 is received in the aperture defined by the back wall 140, and the fixing tips 158 of the fixing brackets 151 are respectively received in the fixing notches 142 of the back wall 140. Third, the front frame 12 and the back cover 16 cooperatively accommodate the display module 13 assembled with the chassis 14 and the locking apparatus 15. The location bolts 167 of the location member 165 respectively extend through the through holes 1526 of the releasing button 152, and the releasing cap 1520 is exposed outside the back cover 16. Fourth, the supporting base 11 is fixed to the display body 10. The coupling ends 113 of the releasing plate 111 are received in the top hatches 163 of the sub-cover 161, and the second fixing protrusions 112 of the releasing plate 111 extend through the bottom hatches 164 to cooperate with the first fixing protrusions 156 of the locking apparatus 15 to fix to each other. Thus, the flat panel display 1 is assembled, and an outmost extremity (not labeled) of the releasing cap 1520 of the releasing button 152 is exposed outside the back cover 16 such that a user can press the releasing cap 1520 inward.

The supporting base 11 can be conveniently detached from the display body 10 as follows. First, an external force is applied to the outmost extremity of the releasing cap 1520 of the releasing button 152 to press the releasing cap 1520 inward. The sliding ribs 1524 push the mobile member 150 to move down, and the first fixing protrusions 156 and the second protrusions 112 are detached from each other. Second, the mobile member 150 recovers to its original position. In particular, after the external force is removed, the elastic member positioned in the aperture elastically pushes the mobile member 150 back to its original position. Third, the flat coupling ends 113 of the releasing plate 111 are downwardly drawn out from the top hatches 163 of the sub-cover 161. Thus, the supporting base 11 is conveniently detached from the display body 10.

In summary, the sliding ribs 1524 of the releasing button 152 is configured to slide along the sliding surfaces 157 of the mobile member 150 with a minimal contact area therebetween, which contact is effectively as little as a surface-to-line type contact. Therefore, there is no need for a great amount of external force to be applied to the releasing button 152 in order to start and maintain the sliding movement to detach the supporting base 11 from the display body 10. Further, the button base 1522 is inseparably formed with the button cap 1520, which eliminates any step of assembling the button cap 1520 to the button base 1522 that might otherwise be required in mass production. Thus, the flat panel display 1 is conveniently assembled and disassembled.

It is believed that the present embodiments and their advantages will be understood from the foregoing description, and it will be apparent that various changes may be made thereto without departing from the spirit or scope of the invention or sacrificing all of its material advantages, the examples hereinbefore described merely being preferred or exemplary embodiments of the invention.

What is claimed is:

1. A flat panel display comprising:
a chassis;
a locking apparatus fixed to the chassis, the locking apparatus comprising:
a mobile member comprising:
at least one sliding surface; and
at least one first fixing protrusion; and
a releasing button comprising:
a button base corresponding to the at least one sliding surface; and
at least one sliding rib provided at the button base, the at least one sliding rib being configured for sliding along the at least one sliding surface; and
a supporting base comprising at least one second fixing protrusion, the at least one first fixing protrusion and the at least one second fixing protrusion being configured to fix to each other such that the supporting base is fixed to the locking apparatus.

2. The flat panel display as claimed in claim 1, wherein the chassis comprises an aperture defined therein for accommodating the mobile member.

3. The flat panel display as claimed in claim 2, wherein the locking apparatus further comprises at least one fixing bracket fixed to the chassis.

4. The flat panel display as claimed in claim 3, wherein the at least one fixing bracket holds the mobile member and allows the mobile member to move up and down along the fixing bracket.

5. The flat panel display as claimed in claim 1, further comprising a back cover configured for accommodating the chassis and the locking apparatus, and the back cover comprises at least two hatches defined therein.

6. The flat panel display as claimed in claim 5, wherein the at least one second protrusion extends through one of the at least two hatches.

7. The flat panel display as claimed in claim 6, wherein the supporting base further comprises at least one flat coupling end positioned opposite to the at least one second fixing protrusion.

8. The flat panel display as claimed in claim 7, wherein the at least one flat coupling end extends through the other one of the at least two hatches.

9. The flat panel display as claimed in claim 1, wherein the back cover further comprises a location member configured for localizing the releasing button.

10. The flat panel display as claimed in claim 9, wherein the location member comprises a through hole defined therein, and at least one location bolt extending toward the releasing button.

11. The flat panel display as claimed in claim 10, wherein the button base comprises at least one fixing hole defined therein, the at least one location bolt extending through the at least one fixing hole.

12. The flat panel display as claimed in claim 1, wherein only a small ridge area of the at least one sliding rib contacts the at least one sliding surface.

13. The flat panel display as claimed in claim 1, wherein the releasing button is made from a mixture of polyoxymethylene and glass fiber.

14. The flat panel display as claimed in claim 1, wherein an outmost extremity of the releasing button is exposed outside the back cover such that a user can press the releasing button inward.

15. The flat panel display as claimed in claim 14, wherein when the outmost extremity of the releasing button is pressed inward, the at least one sliding rib pushes the mobile member to move such that the at least one first fixing protrusions and the at least one second protrusions are detached from each other.

16. The flat panel display as claimed in claim 15, wherein the mobile member further comprises a main body, and the at least one sliding surface is inclined to the main body.

17. A flat panel display comprising:
a display body;
a supporting base configured for supporting the display body; and
a locking apparatus configured for detachably fixing the supporting base to the display body, the locking apparatus comprising:
at least one sliding surface; and
at least one sliding rib corresponding to the at least one sliding surface, the at least one sliding rib being slidable along the at least one sliding surface to detach the supporting base from the display body.

18. The flat panel display as claimed in claim 17, wherein the contact of the at least one sliding rib along the at least one sliding surface is essentially a rectilinear contact.
